(19) United States
(12) Patent Application Publication
(10) Pub. No.: US 2006/0138680 A1
(43) Pub. Date: Jun. 29, 2006

(54) System for controlling semiconductor packaging particulate contamination

(76) Inventor: Phillip D. Weber, Allen, TX (US)

Correspondence Address: TEXAS INSTRUMENTS INCORPORATED, P O BOX 655474, M/S 3999, DALLAS, TX, 75265, US

(21) Appl. No.: 11/021,891

(22) Filed: Dec. 23, 2004

(51) Int. Cl. H01L 23/28

(52) U.S. Cl. 257/787

(57) ABSTRACT

The present invention provides a system for controlling semiconductor packaging particulate contamination. According to the present invention, a semiconductor packaging component (102) is provided, having a first surface (104) along which a plurality of connection features (110, 112) are disposed or located, and an area (202) to which a semiconductor die is to be connected. One or more areas along the first surface are covered with an encapsulant (200) to isolate the area(s) from deleterious stresses and to impede the egress of any particulate matter therefrom.

### TECHNICAL FIELD OF THE INVENTION

The present invention relates generally to the field of semiconductor device packaging and, more particularly, to apparatus and methods for controlling particulate matter contamination emanating from semiconductor package material.

### BACKGROUND OF THE INVENTION

The continual demand for enhanced speed, capacity and efficiency has resulted in dramatic advances in a variety of manufacturing fields (e.g., electronics, communications, machinery). Over time, semiconductor device processes have evolved and expanded in a number of significant ways. Among recent developments, semiconductor and electromechanical fields have focused significant attention on the miniaturization of various devices. A micro-electromechanical system (MEMS) is usually a system that has electrically controllable micro-machines (such as a motor, gear, optical modulating element, etc.) formed monolithically on a semiconductor substrate using integrated circuit techniques.

As production of such highly specialized devices has evolved, those who produce or use semiconductor packages and packaging materials have correspondingly faced an increasing number of significant challenges. Packaging performance levels must be optimized while costs are minimized. Versatile packaging options capable of housing a wide variety of semiconductor devices must be produced economically and efficiently. Packaging must be developed or adapted to comprehend unique device requirements (e.g., moving parts, temperature extremes) while remaining, to the greatest extent possible, compatible with commercially viable production processes.

As with low-complexity semiconductor devices, the successful production of MEMS or other advanced semiconductor devices is frequently impacted by the presence of contaminant material throughout the production or assembly processes. Particulate contamination can be especially problematic in certain MEMS designs; as such devices often rely on extremely fine component movements or deformations. In such designs, stray particulate matter (e.g., package debris) can cause a number of static or dynamic mechanical distortions that may impede or ruin device operation. Moreover, depending upon the composition of particulate matter (e.g., metal), that particulate matter may also impede or ruin electrical performance of a MEMS or advanced semiconductor device by, for example, causing a short between adjacent structures.

In many instances, device packages and packaging materials can be a significant source of particulate contamination. Assembly processes, where a MEMS or semiconductor device is enclosed within or attached to a packaging component, can subject that packaging component to a number of deleterious stressors (e.g., extreme heat, chemicals, mechanical agitation). Those stressors can directly or indirectly cause the separation of particulate debris from a package component (e.g., sloughing, flaking). Furthermore, during the manufacturing of certain packaging components (e.g., a ceramic base), a tradeoff is often made between packaging integrity and packaging cost. Packaging components can be produced of materials having extremely dense, stable lattice structures. As more stable material(s) are used, components are generally less likely to generate particulate debris. Such materials significantly increase the cost of packaging, however, limiting the commercial viability of such an approach. Less expensive materials, having relatively intermittent lattice structures, may be used to improve packaging costs. Unfortunately, however, such package materials are generally more likely to spawn harmful particulate debris.

As a result, there is a need for a system that provides control of particulate matter and debris originating from a semiconductor package component or material, without significantly increasing packaging costs or production overhead—one that is readily adaptable to address a variety of specific device requirements in an easy, efficient and cost-effective manner.

### SUMMARY OF THE INVENTION

The present invention provides a system for controlling the generation of particulate matter and debris originating from semiconductor package components or materials. The system of the present invention provides durable sheathing of all or part of a package component, in a manner that is readily adaptable to a wide variety of package configurations or assembly processes. The system of the present invention provides an easy-to-implement placement/application process for such sheathing. The system of the present invention may utilize a number of readily available assembly apparatus and materials to instantiate such sheathing—thus minimizing the impact of reliable particulate control on packaging costs, production overhead, and device costs.

Specifically, the present invention provides a non-reactive encapsulant to cover or sheath critical portions of a packaging component. The encapsulant is selected or formed to remain durably intact during subsequent handling or assembly. The encapsulant isolates covered package portions from processing or assembly stresses, and serves as a barrier that blocks the egress of any particulate matter that might otherwise escape from the covered package portions. The encapsulant of the present invention may be applied or placed, in one or more phases, at various stages throughout package production or device assembly processes. Depending upon specific design or process requirements, the encapsulant may be selectively applied using a variety of processes such as, for example, photolithography. Depending upon the specific design and materials used, the encapsulant may be left intact throughout a device's lifetime, or removed at some late stage of device assembly.

More specifically, according to the present invention, a semiconductor packaging component is provided, having a first surface along which a plurality of connection features are disposed or located. The first surface also has an area to which a semiconductor die is to be connected. An encapsulant is applied to cover one or more areas along the first surface, isolating the area(s) from deleterious stresses and impeding the egress of any particulate matter therefrom.

The present invention provides methods of preparing a semiconductor packaging component for assembly. These methods comprise providing a first semiconductor packaging component—one that has a first surface to which a semiconductor die is to be connected. An encapsulant is selectively applied to one or more areas along the first surface of the packaging component.

The present invention further provides a semiconductor device comprising a substrate. The substrate has a plurality of bond pads disposed along a first surface thereof. A semiconductor die is attached to the substrate, and operatively coupled to the plurality of bond pads. A package lid is attached to the substrate, forming an enclosure within which the die and bond pads are sealed. An encapsulant is disposed along the first surface of the substrate within the enclosure, exclusive of the plurality of bond pads.

Other features and advantages of the present invention will be apparent to those of ordinary skill in the art upon reference to the following detailed description taken in conjunction with the accompanying drawings.

### BRIEF DESCRIPTION OF THE DRAWINGS

For a better understanding of the invention, and to show by way of example how the same may be carried into effect, reference is now made to the detailed description of the invention along with the accompanying figures in which corresponding numerals in the different figures refer to corresponding parts and in which:

FIG. 1 is an illustration depicting one embodiment of a semiconductor packaging component according to the present invention;

FIG. 2a is an illustration depicting one embodiment of an encapsulant in accordance with the present invention; and

FIG. 2b is an illustration depicting another embodiment of an encapsulant in accordance with the present invention.

### DETAILED DESCRIPTION OF THE INVENTION

While the making and using of various embodiments of the present invention are discussed in detail below, it should be appreciated that the present invention provides many applicable inventive concepts, which can be embodied in a wide variety of specific contexts. For example, certain aspects of the present invention are described, for purposes of explanation and illustration, in conjunction with controlling particulate matter emanating from a ceramic type semiconductor package component housing a micro-electromechanical system (MEMS) device. Upon reference to the description of the present invention, however, it should be readily apparent that the principles and teachings of the present invention may be readily implemented with other device structures and packaging technologies, where controlling particulate contamination in accordance with the present invention is feasible. Therefore, the specific embodiments discussed herein are merely illustrative of specific ways to make and use the invention and do not limit the scope of the invention.

The system of the present invention controls the propagation of particulate matter and debris originating from semiconductor package components or materials. The system of the present invention provides a durable sheathing or coating disposed along of all or part of a package component. The system of the present invention places or applies the sheathing in an easy and efficient manner that is readily adaptable to a wide variety of package configurations or assembly processes. The system of the present invention may be implemented utilizing a number of readily available assembly apparatus and materials, minimizing the impact of reliable particulate control on packaging costs, production overhead, and device costs.

Specifically, the present invention provides a system that utilizes a non-reactive encapsulant to cover or sheath critical portions of a packaging component. The encapsulant is selected or formed to remain durably intact during subsequent package handling and device assembly or processing. Thus, the encapsulant serves not only to isolate covered package portions from processing or assembly stresses, but also serves as a barrier that blocks the egress of any particulate matter that might otherwise escape from the covered package portions. The encapsulant of the present invention may be applied or placed, in one or more phases, at various stages throughout the package production or device assembly processes. Depending upon specific design requirements, and upon process or assembly peculiarities, the encapsulant may be selectively applied using a variety of processes such as, for example, photolithography. Depending upon the specific design and materials, the encapsulant may be left intact throughout a device's lifetime, or removed at some late stage of device assembly.

The present invention comprehends that, in many applications, packaging is a critical part of producing a high-performance semiconductor or MEMS device. Consider, for example, a digital micro-mirror device (DMD™) developed by Texas Instruments Incorporated. The DMD is a spatial light modulation (SLM) device, used to modulate incident light in a spatial pattern to form an image corresponding to an electrical or optical input. A DMD is a monolithic single chip circuit, having a high-density array of moveable micro-mirrors fabricated over address circuitry. More detailed discussions of a DMD device and its use may be found in the following patents: U.S. Pat. No. 5,061,049; U.S. Pat. No. 5,079,544; U.S. Pat. No. 5,105,369; and U.S. Pat. No. 5,278,652. Each of these patents is assigned to Texas Instruments Incorporated.

In order to avoid sticking or other malfunction amongst the mirrors, a DMD device is typically packaged in a controlled environment, having minimal amounts of moisture, adhesive, dust, and other contaminants. This is generally accomplished by packaging a DMD device in a hermetically sealed package. These packages commonly comprise custom designed ceramic substrates and expensive glass covers or lids, which are seam welded or fixed in place upon the substrate with an adhesive. Such packages are not only expensive, but also require a significant degree of handling and processing to assemble a complete and functional device.

In a DMD assembly process, for example, a ceramic substrate may be produced, having metallic external pin connections on one side, and corresponding bond pads along an opposite side. Often, such ceramic substrates are formed to withstand operational extremes (e.g., high temperature) and thus comprise certain materials suitable for such conditions (e.g., tungsten). Furthermore, the ceramic substrate may be produced with a variety of metallic material (e.g., Al) routed throughout, electrically coupling corresponding bond pads and connections together. A weld ring may be attached to the substrate, surrounding the bond pads. A die may be attached to the substrate within the weld ring (e.g., by epoxy). Wire-bonding may be performed to intercouple the bond pads to the die. A cover or lid may then be attached (e.g., by welding, by epoxy) to seal and complete the device.

Even in such an overly simplified assembly process, a ceramic substrate experiences a number of stresses that can damage structural integrity of its surfaces. Given certain physical and reactive properties of materials within the ceramic substrate, exposure to a number of handling, heating, chemical and impact stressors can cause a variety of breaches or ruptures of the ceramic surface—resulting in flaking or sloughing of package particulate matter. Depending upon the composition of the particulate matter (e.g., aluminum oxide), and the assembly stage at which it is generated, contamination of a device's hermetic environment may occur. DMD devices that rely on slight movements of extremely small features can be drastically impaired by a minute amount of contaminant matter. Thus, even minimal package particulate contamination can significantly degrade device performance or render a DMD device completely inoperable. In a more general sense, a number of MEMS devices (e.g., micro-motors, gears) and circuits can be significantly impacted by such contamination.

Theoretically, ceramic packages having highly dense, durable material properties might be used in an effort to reduce such package-related particulate contamination. Practically, however, complete elimination of such contamination is not feasible. Fabrication, transport, cleaning, handling or assembly processes, or combinations thereof, usually result in at least some degree of package particulate matter. Using package materials of superior density or durability might reduce or minimize particulate generation, but generally can't eliminate it completely. Furthermore, packaging produced from such superior materials would greatly increase the cost of already expensive package components. Where a less expensive—and less robust—packaging material is used, particulate generation is typically greater, and may occur in uneven distribution across a surface area.

Comprehending these and other related issues, the present invention provides a system by which a relatively inexpensive packaging component may be utilized without generating a significant amount of, or any, particulate contamination. The system of the present invention coats or sheaths a desired area or portion of a packaging component with an encapsulant material. Once the encapsulant of the present invention has been disposed along a certain area, that area is isolated from interaction with other materials, elements or chemicals. The encapsulant thus protects the desired area from external stressors, and prevents the egress of any particulate matter from that area. The encapsulant may be selectively applied to one or more desired area(s) along a surface or object, using readily available screening or photolithography processes. The encapsulant can be selectively masked or screened away from device connectivity or assembly features (e.g., bond pads) along a package surface. This selective application provides users of the present invention with the ability to optimize cost, efficiency and yield of packaging processes.

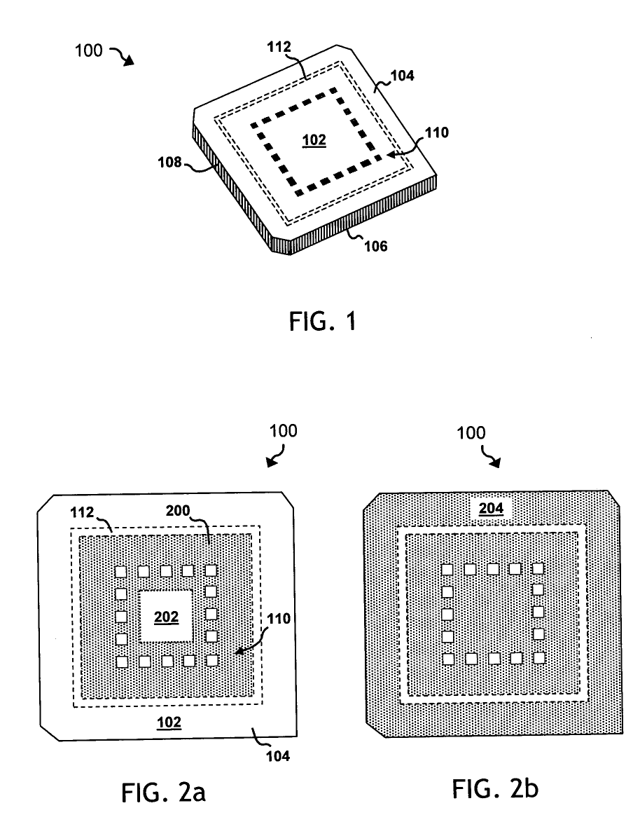

Certain aspects of the present invention are described and illustrated in greater detail, beginning now with reference to FIG. 1. For purposes of explanation and illustration, FIG. 1 depicts the system of the present invention in relation to a DMD packaging process, utilizing a packaging component 100. Component 100 comprises a ceramic packaging substrate 102, having an upper surface 104 and a lower surface 106, as well as an outer perimeter edge 108. A pattern or array of device bond pads 110 are formed or disposed along surface 104, near or around the center thereof. Along an outer perimeter of surface 104, near edge 108, a weld ring footprint 112 is indicated. Depending upon the materials and processes used, footprint 112 may comprise an actual formation (e.g., metallic line, scribe) along surface 104 or, alternatively, may just serve as a virtual reference point for the eventual placement of a weld ring (not shown).

As shown now in reference to FIG. 2a, an encapsulant 200 is applied to or deposited upon a portion of surface 104. In this embodiment, encapsulant 200 is patterned to cover only exposed ceramic substrate within the area bounded by footprint 112, exclusive of the bond pad areas 110. Openings or voids in encapsulant 200 (e.g., over areas 110) may be provided by some suitable masking of those areas during the placement or application of encapsulant 200. Depending upon the nature of component 102 and its packaging application, other embodiments may also leave (by, e.g., masking) an exposed ceramic area 202 at the center of encapsulant 200 to accommodate subsequent handling or assembly requirements—such as the adhesive attachment of a die to surface 104, for example.

In the embodiment depicted in FIG. 2b, an encapsulant 204 is applied to or deposited upon surface 104, such that encapsulant 204 covers all exposed ceramic substrate along surface 104, exclusive of footprint 112 and the bond pad areas 110. Openings or voids in encapsulant 200 (e.g., over areas 110) may be provided by some suitable masking of those areas during the placement or application of encapsulant 200. Depending upon the nature of omponent 102 and its packaging application, alternative embodiments may also apply encapsulant around edge 108, or along part or all of surface 106, exclusive of external pin connections thereupon, effectively sheathing or covering all exposed ceramic surfaces. Thus, according the present invention, encapsulant may be selective placed or applied, in a discrete or contiguous manner, to isolate selected surfaces of a packaging component.

An encapsulant according to the present invention may be comprised of a wide variety of suitable materials, depending upon factors such as: package component materials, package handling, assembly conditions (e.g., heat, chemicals), and end-equipment applications. In certain embodiments, for example, industrial thick film compositions (e.g., glass encapsulant, solder dam) may be selectively applied using screen-printing or semiconductor lithography techniques. In still other embodiments, different encapsulant materials may used, or multiple encapsulant materials may be independently instantiated in different areas of a single packaging component. Depending upon the specific properties of the selected encapsulant(s), the final thickness of the encapsulant should be sufficient to securely cover the desired area, throughout device assembly and operation, without detrimentally affecting device performance or usage. For example, in embodiments where a thick-film glass encapsulant is applied using a firing process, a final, post-assembly thickness of about 3μ to 5μ may be desired.

According to the present invention, encapsulant(s) may be applied at a number of points throughout the package production or device assembly processes. As a practical matter, of course, encapsulant should be applied prior to the final sealing of the packaging component (e.g., the final welding of a DMD lid). Depending upon the nature of the particular device, it may be further desirable to deposit or place the encapsulant prior to the attachment of the die to the package. In a DMD device, for example, depositing encapsulant underneath an already attached die can be tedious and inefficient, if possible at all. Further depending upon the production and handling process for the packaging component, it may be desirable to apply the encapsulant after the component has been cleaned, just prior to attachment of correlated packaging components. For example, it may be useful to place encapsulant on a ceramic DMD substrate after it has been thoroughly cleaned to remove any existing particulate matter, but just prior to attachment of a weld ring. If an encapsulant is not durable enough to withstand the attachment (i.e., sintering) of a weld ring, it may be desirable to apply the encapsulant after the weld ring is already attached. Thus, according to the present invention, an encapsulant coating may be applied at various points throughout a production or assembly process—providing optimizable particulate control for a given package, device, or process.

Thus, according to the present invention, one or more encapsulants are applied to one or more surfaces or areas of a packaging component, to inhibit or eliminate the generation or egress of particulate matter therefrom. The system of the present invention is extremely versatile and readily adaptable to a number of material or process considerations. The present invention thus provides efficient and effective control of package-related particulate contamination in a semiconductor or MEMS device.

As previously discussed, the embodiments and examples set forth herein are therefore presented to best explain the present invention and its practical application, and to thereby enable those skilled in the art to make and utilize the invention. However, those skilled in the art will recognize that the foregoing description and examples have been presented for the purpose of illustration and example only. The description as set forth is not intended to be exhaustive or to limit the invention to the precise form disclosed. As indicated, a number of modifications and variations are possible in light of the above teaching without departing from the spirit and scope of the following claims.

What is claimed is:

1. A method of preparing a semiconductor packaging component for assembly, the method comprising the steps of:
providing a first semiconductor packaging component, having a first surface to which a semiconductor die is to be connected; and
selectively applying an encapsulant to one or more areas along the first surface.

2. The method of claim 1, wherein the step of providing a first semiconductor packaging component further comprises providing a ceramic substrate.

3. The method of claim 2, wherein the step of providing a ceramic substrate further comprises providing a substrate containing aluminum oxide.

4. The method of claim 1, wherein the step of providing a first semiconductor packaging component having a first surface to which a semiconductor die is to be connected further comprises providing a ceramic substrate having a first surface, comprising a plurality of device features, to which a semiconductor die is to be connected.

5. The method of claim 4, wherein the step of selectively applying an encapsulant to one or more areas along the first surface further comprises selectively masking the plurality of device features from the encapsulant.

6. The method of claim 1, wherein the step of providing a first semiconductor packaging component further comprises providing a MEMS packaging component.

7. The method of claim 1, wherein the step of providing a first semiconductor packaging component further comprises providing a DMD packaging component.

8. The method of claim 1, wherein the step of selectively applying an encapsulant to one or more areas along the first surface further comprises applying a thick-film encapsulant to one or more areas along the first surface.

9. The method of claim 1, wherein the step of selectively applying an encapsulant to one or more areas along the first surface further comprises selectively applying the encapsulant using a screen printing process.

10. The method of claim 1, wherein the step of selectively applying an encapsulant to one or more areas along the first surface further comprises selectively applying the encapsulant using a photolithographic process.

11. The method of claim 1, wherein the encapsulant is applied prior to connection of the semiconductor die to the first surface.

12. A semiconductor device comprising:
a substrate, having a plurality of bond pads disposed along a first surface thereof;
a semiconductor die, attached to the substrate and operatively coupled to the plurality of bond pads;
a package lid, attached to the substrate, forming an enclosure within which the die and bond pads are sealed; and
an encapsulant, disposed along the first surface of the substrate within the enclosure, exclusive of the plurality of bond pads.

13. The device of claim 12, wherein the substrate comprises a ceramic substrate.

14. The device of claim 12, wherein the substrate comprises aluminum oxide.

15. The device of claim 12, wherein the semiconductor die comprises a MEMS device.

16. The device of claim 12, wherein the semiconductor die comprises a DMD device.

17. The device of claim 12, wherein the encapsulant comprises a thick-film encapsulant.

18. The device of claim 12, wherein the encapsulant comprises a glass encapsulant.

19. The device of claim 12, further comprising encapsulant disposed along the substrate external to the enclosure.

20. A system for controlling semiconductor packaging particulate contamination, the system comprising:
a semiconductor packaging component, having a first surface to which a semiconductor die is to be connected;
cleaning the first surface; and
selective covering of one or more areas along the first surface with an encapsulant prior to connection of the semiconductor die.
